(19) United States
(12) Patent Application Publication
(10) Pub. No.: US 2013/0119484 A1
(43) Pub. Date: May 16, 2013

(54) SEMICONDUCTOR DEVICE AND METHOD FOR MANUFACTURING THE SAME

(71) Applicants: Haizhou Yin, Poughkeepsie, NY (US); Zhijiong Luo, Poughkeepsie, NY (US); Huilong Zhu, Poughkeepsie, NY (US)

(72) Inventors: Haizhou Yin, Poughkeepsie, NY (US); Zhijiong Luo, Poughkeepsie, NY (US); Huilong Zhu, Poughkeepsie, NY (US)

(21) Appl. No.: 13/063,907

(22) PCT Filed: Feb. 27, 2011
(86) PCT No.: PCT/CN11/71347

§ 371 Date: Mar. 14, 2011

(30) Foreign Application Priority Data
Jul. 30, 2010 (CN) 201010240551.7

(51) Int. Cl. H01L 29/51; H01L 29/40

(52) U.S. Cl. CPC H01L 29/518; H01L 29/401
USPC 257/410; 438/591

(57) ABSTRACT

The present invention provides a method of manufacturing a semiconductor device comprising: providing a semiconductor substrate, on which a high-k dielectric layer and a patterned gate are formed sequentially; nitridating portions of the high-k dielectric layer on the semiconductor substrate which are not covered by the gate; and forming spacers around the gate. Accordingly, the present invention further provides a semiconductor device. Portions of the high-k dielectric layer on the semiconductor substrate, which are not covered by the gate or the spacers positioned thereon, are nitridated, such that an oxygen diffusion barrier layer is formed on the surface of the high-k dielectric layer, thereby oxygen diffusion in the lateral direction into the high-k dielectric layer under the gate is prevented, and the operation performance of the semiconductor device is optimized.

### FIELD OF THE INVENTION

The present invention relates to the technical field of semiconductor manufacturing, and specifically, to a semiconductor device capable of preventing oxygen from diffusing in the lateral direction into a high dielectric constant (high-k) gate dielectric layer and a method for manufacturing the same.

### BACKGROUND OF THE INVENTION

With continuous proportional scaling in size of semiconductor devices, particularly, as the semiconductor manufacturing process comes into sub-90 nm technical node, the thickness of the gate oxide layer is becoming thinner. However, when the thickness of a gate oxide layer is smaller than 10 nm, the increase of the gate leakage current arising from the very thin gate oxide layer may cause negative effects to the performance of a semiconductor device.

In the trend of proportional scaling in sizes of semiconductor devices, for the purpose of increasing the thickness of the gate oxide layer in the semiconductor device so as to prevent generation of the gate leakage current, more high-k materials (for example, HfO₂, HfSiO, HfSiON, HfTaO, HfTiO, HfZrO, Al₂O₃, La₂O₃, ZrO₂, LaAlO or the like) are used for gate dielectric layers of semiconductor devices. Nonetheless, in the process of manufacturing a semiconductor device, the oxygen in the process chamber will diffuse into a high-k dielectric layer, which may cause regrowth of the high-k gate dielectric layer and also variation of the thickness of an interfacial oxide layer of the high-k gate dielectric layer, and would degrade the overall geometry shape and uniformity of the device, thereby further impairing the electric performance of the semiconductor device.

Therefore, two approaches are provided in the prior art to reduce the oxygen diffusion into the high-k gate dielectric layer of the semiconductor device. For the case of oxygen diffusion in the vertical direction into the high-k gate dielectric layer, US Patent Publication US 2009/0108366 A1 discloses a method for substantially preventing oxygen diffusion into high-k gate dielectric layers 20, 32 in the direction vertical to the gate by means of amorphous silicon layers 24, 36 positioned above high-k/metal gate stacks 26, 38 (as shown in FIG. 1). However, the above-mentioned method is only capable of preventing oxygen diffusion in the vertical direction into the high-k gate dielectric layer, but is unable to prevent oxygen diffusion in the lateral direction into the high-k gate dielectric layer. For the case of oxygen diffusion in the lateral direction into a high-k gate dielectric layer, US Patent Publication US 2009/0079014 A1 discloses a method for preventing oxygen diffusion in the lateral direction into a high-k gate dielectric layer 102 by a high-k liner layer 106 covering an active area of a semiconductor device and surrounding the whole gate (as shown in FIG. 2). However, because the high-k dielectric layer 106 is only made of a common high-k material, the above-mentioned method only achieves limited effect of preventing oxygen diffusion in the lateral direction into a high-k gate dielectric layer, and is unable to fully satisfy the requirements in the process of manufacturing semiconductor devices in practice.

Besides, the Chinese Patent Publication No.: CN1875463A discloses a method for integrating a high-k gate dielectric in a transistor fabrication process, which performs a nitridation process on a gate stack of the whole transistor. A barrier layer is formed at side surfaces of the high-k dielectric segment in the gate stack by introducing nitrogen into sides of the high-k dielectric segment, so as to prevent the oxygen diffusion in the lateral direction into the high-k dielectric segment during subsequent processing steps. However, in the above-mentioned method, the nitrogen is introduced directly into sides of the high-k dielectric segment which is served as a gate dielectric layer under the gate, consequently reducing the carrier mobility in the channel region of a transistor, and further causing negative effects to the operation performance of the whole transistor.

### SUMMARY OF THE INVENTION

The present invention provides a semiconductor device capable of preventing oxygen diffusion in the lateral direction into a high dielectric constant (high-k) gate dielectric layer and a method for manufacturing the same, thereby preventing re-growth of the high-k gate dielectric layer or an increase of the thickness of an interfacial oxide layer thereof, which may improve the operation performance of the semiconductor device accordingly.

For the purpose of solving the aforesaid problem, the present invention proposes a method for manufacturing a semiconductor device, which comprises: providing a semiconductor substrate, on which a high-k dielectric layer and a patterned gate are formed sequentially; nitridating portions of the high-k dielectric layer on the semiconductor substrate which are not covered by the gate; and forming spacers around the gate. The sequences for performing the step of forming spacers and the step of nitridating the high-k dielectric layer may be exchanged.

Optionally, the nitrogen content in the nitridated high-k dielectric layer in the semiconductor device is that the percentage of the nitrogen atoms is more than 10%.

Optionally, a nitridated periphery portion of the high-k dielectric layer covered by the gate has a lateral dimension not larger than 3 nm.

The present invention further provides a method for manufacturing a semiconductor device, which comprises: providing a semiconductor substrate, on which a high-k dielectric layer and a patterned gate are formed sequentially; forming spacers around the gate; and nitridating portions of the high-k dielectric layer on the semiconductor substrate which are not covered by both the gate and the spacers.

Optionally, the nitrogen content in terms of atomic percentage in the nitridated high-k dielectric layer in the semiconductor device is 10% greater than that in the high-k dielectric layer that has not been nitridated.

The present invention further provides a semiconductor device, which comprises: a semiconductor substrate, on which a high-k dielectric layer and a patterned gate are formed sequentially; spacers formed around the gate; a high-k dielectric layer on the semiconductor substrate, wherein the high-k dielectric layer has nitridated portions in a region which is not covered by the gate, and further has nitridated portions between the semiconductor substrate and the spacers.

Optionally, the nitrogen content in the nitridated high-k dielectric layer in the semiconductor device has an atomic percentage of nitrogen more than 10%.

Compared with the prior art, the present invention has the following advantages: portions of the high-k dielectric layer on the semiconductor substrate which are not covered by a gate or a spacer thereon are nitridated, such that nitrogen is diffused into the above-mentioned portions of the high-k dielectric layer to form an oxygen diffusion barrier layer on the surface thereof, which therefore may prevent oxygen from diffusing in the lateral direction into the high-k dielectric layer that serves as a gate dielectric layer under the gate during the subsequent manufacturing process steps. As a result, the high-k dielectric layer serving as the gate dielectric layer is safeguarded from oxygen diffusion from the outside, and the re-growth of high-k gate dielectric layer is suppressed accordingly. In addition, since the nitridation process is not applied directly to the semiconductor device, the carrier mobility in the channel region of a transistor may not be reduced by the nitridation process, which thus optimizes the operation performance of the semiconductor device.

Other characteristics and advantages of the present invention are made more evident according to the following detailed description of exemplary embodiment(s) and the accompanying drawings.

### BRIEF DESCRIPTION OF THE DRAWINGS

FIG. 1 illustrates a structural schematic diagram of a semiconductor device in prior art for preventing oxygen from diffusing in a direction vertical to a gate into a high-k gate dielectric layer;

FIG. 2 illustrates a structural schematic diagram of a semiconductor device in prior art for preventing oxygen diffusing in the lateral direction into a high-k gate dielectric layer;

FIG. 3 is a flowchart of a method for manufacturing a semiconductor device for preventing oxygen diffusion in the lateral direction according to a first embodiment of the present invention;

FIG. 4 is a flowchart of a method for manufacturing a semiconductor device for preventing oxygen diffusion in the lateral direction according to a second embodiment of the present invention;

FIG. 5 to FIG. 8 illustrate cross-sectional structural schematic diagrams of the respective stages in manufacturing a semiconductor device for preventing oxygen diffusion in the lateral direction as per the flowchart shown in FIG. 3 according to the first embodiment of the present invention;

FIG. 9 and FIG. 10 illustrate cross-sectional structural schematic diagrams of the respective stages in manufacturing a semiconductor device for preventing oxygen diffusion in the lateral direction as per the flowchart shown in FIG. 4 according to the second embodiment of the present invention.

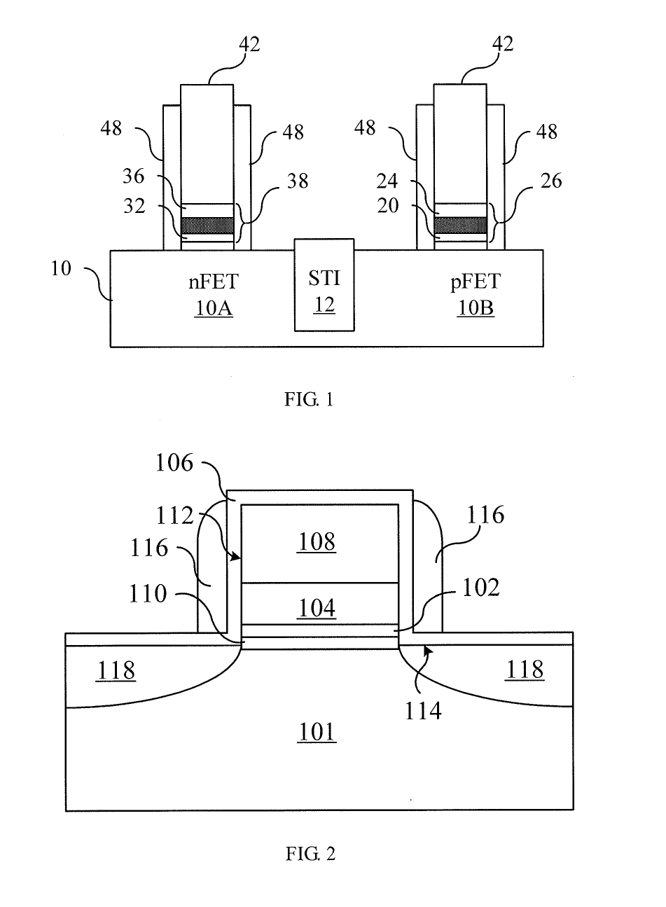

### DETAILED DESCRIPTION OF THE INVENTION

The present invention is further described with the specific exemplary embodiments and the accompanying drawings, but the scope of the present invention is not limited thereto.

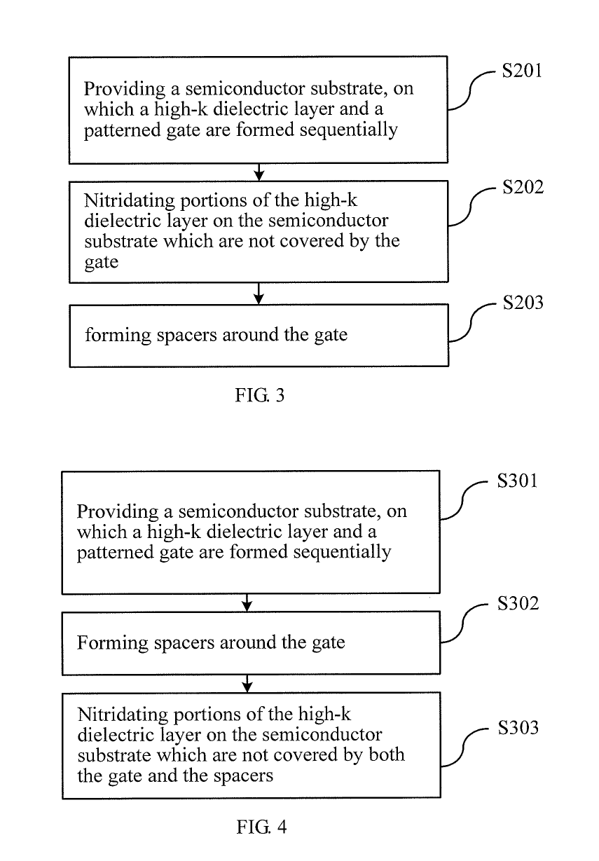

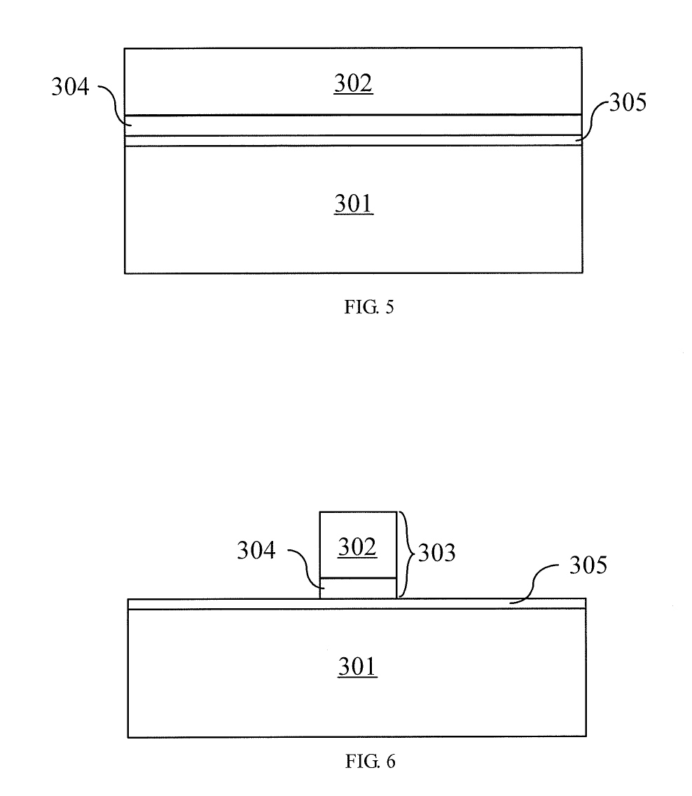

FIG. 3 is a schematic flowchart of a method for manufacturing a semiconductor device for preventing oxygen diffusion in the lateral direction according to the first embodiment of the present invention. FIG. 5 to FIG. 8 illustrate cross-sectional structural schematic diagrams of the respective stages in manufacturing a semiconductor device for preventing oxygen diffusion in the lateral direction as per the flowchart shown in FIG. 3 according to the first embodiment of the present invention. The first embodiment of the present invention is described below with reference to FIG. 3 and FIG. 5 to FIG. 8.

As shown in FIG. 3 and FIGS. 5-8, the method for manufacturing the semiconductor device according to the first embodiment of the present invention comprises the following steps.

In step S201, a semiconductor substrate 301 is provided, on which a high-k dielectric layer 305 and a patterned gate stack 303 are formed sequentially. FIG. 5 illustrates a cross-sectional structure of a semiconductor device before formation of the patterned gate stack 303. Said structure comprises a semiconductor substrate 301, and a high-k dielectric layer 305, a metal layer 304 and an electrode layer 302 formed thereon sequentially. The semiconductor substrate 301 is generally a silicon substrate. The high-k dielectric layer 305 may be any one of HfO₂, HfSiO, HfSiON, HfTaO, HfSiO, HfZrO, Al₂O₃, La₂O₃, ZrO₂, and LaAlO, or any combination thereof. It should be noted that the high-k dielectric materials mentioned above and given in other parts of the present application are merely particular examples, and therefore other high-k dielectric materials are also applicable. Thus, the present invention is not limited to the high-k dielectrics mentioned herein. In a variation of the present embodiment, the thickness of the high-k dielectric layer 305 is in the range of 0.7 nm to 3 nm. The metal layer 304 serves for work function control, and may comprise such materials as TiN, TiAlN, TaN, TaAlN, TaC, or any combination thereof, with a thickness of, for example, 6-20 nm. The materials for the electrode layer 302 are, for example, silicon, metals or metallic silicon or the like.

FIG. 6 illustrates a cross-sectional structure of the semiconductor device after formation of the patterned gate stack 303 formed by etching the electrode layer 302 and the metal layer 304. As shown in the figure, etching is applied sequentially to the electrode layer 302 and the metal layer 304, and then stops at the high-k dielectric layer 305. The remaining parts of the electrode layer 302 and the metal layer 304 form the patterned gate stack 303.

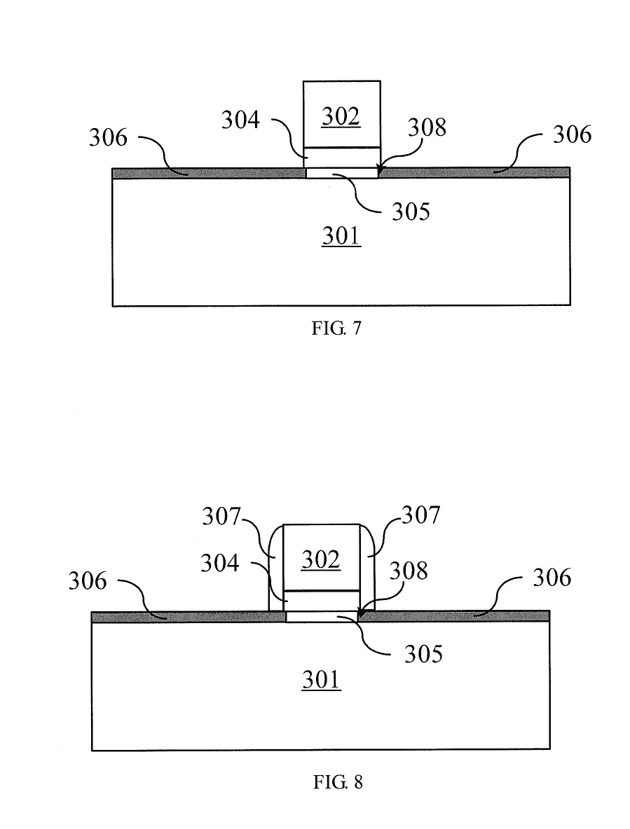

Next, in step S202, the portions of the high-k dielectric layer exposed on the semiconductor substrate are nitridated. As shown in FIG. 7, the portions of the high-k dielectric layer 305 on the semiconductor substrate 301, which are not covered by the gate stack 303, are nitridated, so as to form a nitridated high-k dielectric layer 306. The nitridation process may be performed in accordance with the prior art known by a person of ordinary skill in the art. For example, the exposed surface of the high-k dielectric layer 305 may be nitridated by plasma containing nitrogen. Since the nitridated high-k dielectric layer 306 forms a barrier layer around the un-nitridated high-k dielectric layer 305 that is covered by the gate stack 303, the disadvantageous oxygen diffusion in a lateral direction arising from the subsequent process steps may be effectively suppressed.

In the present embodiment, the nitrogen content in the nitridated high-k dielectric layer 306 has an atomic percentage of nitrogen more than 10%. Namely, the number of nitrogen atoms in the nitridated high-k dielectric layer 306 accounts for more than 10% of the total number of atoms. Generally, the high-k dielectric layer with a higher nitridation level may have stronger capability of preventing oxygen diffusion in a lateral direction. Besides, since the exposed high-k dielectric layer is not situated in a channel region, the intensive nitridation process to the exposed high-k dielectric layer may not reduce the carrier mobility within the channel region.

During the nitridation process of the present embodiment, a periphery portion 308 of the nitridated high-k dielectric layer 306 near the gate stack 303 may extend to under the gate stack 303. However, since nitridation is performed to the exposed surface of the high-k dielectric layer 305, while the side surface of the periphery portion 308 of the high-k dielectric layer 305 covered by the gate stack 303 is not exposed to be directly nitridated, the nitridated portion of the periphery portion 308 extending laterally towards the gate region generally has a dimension not larger than 3 nm, which may not lead to reduction of the carrier mobility within the channel region of a transistor, and may not significantly affect the overall operation performance of the semiconductor device. Besides, the partial extension of the nitridated portion towards the gate region may also effectively prevent oxygen diffusion from the interface between the gate stack 303 and the high-k dielectric layer 305 into the un-nitridated portions in the high-k dielectric layer 305.

Then, in step S203, spacers are formed around the gate. As shown in FIG. 8, spacers 307 are formed around the gate stack 303 for facilitating the subsequent semiconductor manufacturing process. The materials for spacers 307 may be any one of SiO₂, Si₃N₄, and SiON, or any combination thereof, and preferably a silicon nitride material, with a thickness in the range of 7-40 nm.

So far, the portions of the nitridated high-k dielectric layer 306 overlapped with the spacers 307 become the critical region for preventing oxygen from diffusing in the lateral into the high-k dielectric layer which is served as a gate dielectric layer under the gate stack 303.

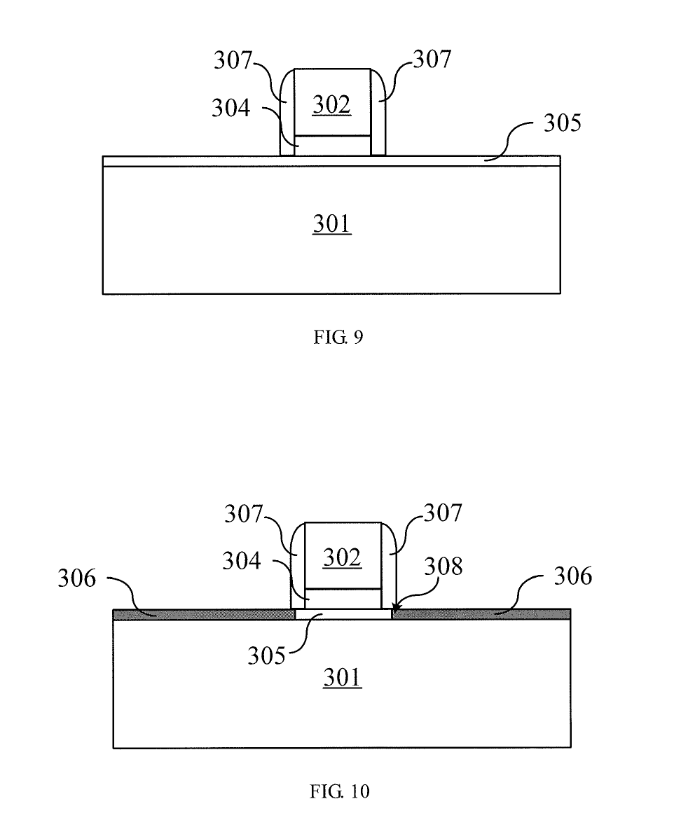

FIG. 4 is a flowchart of a method for manufacturing a semiconductor device for preventing oxygen diffusion in the lateral direction according to the second embodiment of the present invention. FIG. 9 and FIG. 10 illustrate cross-sectional structural schematic diagrams of the respective stages in manufacturing the semiconductor device for preventing oxygen diffusion in the lateral direction according to the second embodiment of the present invention. The second embodiment of the present invention is described below with reference to FIG. 4, FIG. 9 and FIG. 10.

As shown in FIGS. 4, 9 and 10, the method for manufacturing the semiconductor device of the second embodiment of the present invention comprises the following steps.

According to the same manner as the first embodiment, the present flow begins with step S301 of providing a semiconductor substrate 301, on which a high-k dielectric layer 305 and a patterned gate stack 303 are formed sequentially. The structure obtained after completion of step S301 is shown in FIG. 6. Step S201 of the foregoing first embodiment may be referred to for the specific implementation, and the same part is omitted so as not to obscure the understanding.

Next, in step S302, spacers 307 are formed around the gate stack 303. The materials for the spacers 307 may comprise any one of SiO₂, Si₃N₄ and SiON, or any combination thereof, with a thickness in the range of 10-100 nm, as shown in FIG. 9.

Then, in step S303, the portions of the high-k dielectric layer on the semiconductor substrate, which are not covered by the gate stack 303 and spacers 307, are nitridated, as shown in FIG. 10. The nitridation process may be performed in accordance with the prior art known by a person of ordinary skill in the art. For example, the plasma containing nitrogen may be applied to nitridate the exposed surface of the high-k dielectric layer 305.

In the present embodiment, the nitrogen content in the nitridated high-k dielectric layer has an atomic percentage of nitrogen more than 10%. Namely, the number of nitrogen atoms in the nitridated high-k dielectric layer 306 accounts for more than 10% of the total number of atoms.

As shown in FIG. 10, during the nitridation process of the present embodiment, a periphery portion 308 of the nitridated high-k dielectric layer 306 near the spacers 307 may extend to under the spacers 307. However, since nitridation is performed to the exposed surface of the high-k dielectric layer 305, while the side surface of the periphery portion 308 of the high-k dielectric layer 305 covered by the spacers 307 is not exposed to be directly nitridated, the nitridated portion of the periphery portion 308 extending laterally to under the spacers 307 generally has a dimension not larger than 3 nm, and may not reach the high-k gate dielectric layer under the gate stack 303, and therefore may not lead to reduction of the carrier mobility in the channel region of a transistor. In addition, the extension of the nitridated portion to under the spacers 307 is also able to effectively prevent oxygen diffusion from an interface between the spacers 307 and the high-k dielectric layer 305 into the un-nitridated portions in the high-k dielectric layer 305. Therefore, the re-growth of the high-k dielectric layer 305 will not occur.

So far, the portions of the nitridated high-k dielectric layer 306 overlapped with the spacers 307 become the critical region for preventing oxygen from diffusing in the lateral direction into the high-k dielectric layer which is served as the gate dielectric layer under the gate.

The main difference between the second embodiment and the first embodiment of the present invention is that the sequence of the step for forming spacers 307 and the step for performing nitridation process is reversed. However, both of the two embodiments are capable of realizing the object of the present invention to prevent oxygen from diffusing in the lateral direction into the high-k dielectric layer 305 under the gate stack 303.

In accordance with the present invention, the portions of the high-k dielectric layer on the semiconductor substrate, which are not covered by the gate or the spacers thereon, are nitridated such that nitrogen is introduced into said portions of the high-k dielectric layer to form an oxygen diffusion barrier layer on the surface thereof, which therefore prevents oxygen from diffusing in the lateral direction into the high-k dielectric layer serving as the gate dielectric layer under the gate during the subsequent manufacturing process steps, and consequently the high-k dielectric layer serving as the gate dielectric layer is not affected by oxygen diffusion from outside, and the re-growth of high-k gate dielectric layer is suppressed accordingly. In addition, since the nitridation process is not applied directly to the semiconductor device, the nitridated region may not be formed into the high-k gate dielectric layer, such that the nitridation process may not lead to reduction of the carrier mobility in the channel region of the transistor, which thus optimizes the operation performance of the semiconductor device.

After completion of the step for forming spacers 307 and the step for performing nitridation process according to the first embodiment or the second embodiment, the conventional semiconductor manufacturing processes may be implemented subsequently. For example, ion implant may be performed to form an extension region and/or a halo region; a second spacer (for example, with a thickness of 7-40 nm) is formed around the gate for preventing shorts between the channel and source/drain and/or silicide of source/drain regions in the completed semiconductor device; and/or ion implant is performed to form source/drain.

Moreover, in the method for manufacturing a semiconductor device of the present invention, the high-k dielectric layer(s) 305 and/or 306 has/have not been etched away, the high-k dielectric layer may function as an etching barrier layer when the patterned gate stack 303 is formed and spacers 307 are formed by, for example, anisotropic etching, which may reduce the number of masks and simplify the process.

The present invention is disclosed by way of preferred embodiments, however, it is not limited thereto. Any possible modification and alternation may be made by a person of ordinary skill in the art without departing from the spirit and scope of the present invention. Accordingly, the scope of the present invention is defined by the appended claims of the present invention.

1. A method for manufacturing a semiconductor device, comprising:
providing a semiconductor substrate, on which a high-k dielectric layer and a patterned gate are formed sequentially;
nitridating portions of the high-k dielectric layer on the semiconductor substrate which are not covered by the gate; and
forming spacers around the gate.

2. The method according to claim 1, wherein the nitrogen content in the nitridated high-k dielectric layer in the semiconductor device has an atomic percentage of nitrogen more than 10%.

3. The method according to claim 1, wherein a nitridated periphery portion of the high-k dielectric layer covered by the gate has a lateral dimension not larger than 3 nm.

4. A method for manufacturing a semiconductor device, comprising:
providing a semiconductor substrate, on which a high-k dielectric layer and a patterned gate are formed sequentially;
forming spacers around the gate; and
nitridating portions of the high-k dielectric layer on the semiconductor substrate which are not covered by both the gate and the spacers.

5. The method according to claim 4, wherein the nitrogen content in the nitridated high-k dielectric layer in the semiconductor device has an atomic percentage of nitrogen more than 10%.

6. The method according to claim 4, wherein a nitridated periphery portion of the high-k dielectric layer covered by the spacers has a lateral dimension not larger than 3 nm.

7. A semiconductor device comprising:
a semiconductor substrate with a high-k dielectric layer and a patterned gate formed thereon in sequence;
spacers formed around the gate;
wherein the high-k dielectric layer has a nitridated portion on the semiconductor substrate which is not covered by the gate.

8. The semiconductor device according to claim 7, wherein the high-k dielectric layer has another nitridated portion between the semiconductor substrate and the spacers.

9. The semiconductor device according to claim 7, wherein the high-k dielectric layer has an un-nitridated portion between the semiconductor substrate and the gate.

10. The semiconductor device according to claim 7, wherein the nitrogen content in the nitridated high-k dielectric layer in the semiconductor device has an atomic percentage of nitrogen more than 10%.

11. The semiconductor device according to claim 7, wherein a nitridated periphery portion of the high-k dielectric layer covered by the gate has a lateral dimension not larger than 3 nm.

12. The method according to claim 2, wherein a nitridated periphery portion of the high-k dielectric layer covered by the gate has a lateral dimension not larger than 3 nm.

13. The method according to claim 5, wherein a nitridated periphery portion of the high-k dielectric layer covered by the spacers has a lateral dimension not larger than 3 nm.

14. The semiconductor device according to claim 8, wherein the high-k dielectric layer has a un-nitridated portion between the semiconductor substrate and the gate.

15. The semiconductor device according to claim 8, wherein a nitridated periphery portion of the high-k dielectric layer covered by the gate has a lateral dimension not larger than 3 nm.
